(19) United States
(12) Patent Application Publication
(10) Pub. No.: US 2024/0079208 A1
(43) Pub. Date: Mar. 7, 2024

(54) PLASMA PROCESSING APPARATUS

(71) Applicant: Tokyo Electron Limited, Tokyo (JP)

(72) Inventors: Takeshi KOBAYASHI, Iwate (JP); Michitaka AITA, Yamanashi (JP)

(21) Appl. No.: 18/240,010

(22) Filed: Aug. 30, 2023

(30) Foreign Application Priority Data
Sep. 1, 2022 (JP) 2022-139198

(51) Int. Cl. H01J 37/32

(52) U.S. Cl. CPC H01J 37/32091; H01J 37/32568; H01J 37/32834

(57) ABSTRACT

A plasma processing apparatus includes: a processing container; a substrate holding unit that disposes a plurality of substrates in multiple tiers and is inserted into the processing container; a rotary shaft that rotates the substrate holding unit; a gas supply unit that supplies a processing gas into the processing container; an exhaust unit that exhausts the inside of the processing container; a plurality of electrodes disposed on the outer side of the processing container and arranged in the circumferential direction of the processing container; and a radio-frequency power supply that applies a radio-frequency power to the plurality of electrodes, thereby generating capacitively coupled plasma in the processing container.

### CROSS-REFERENCE TO RELATED APPLICATIONS

This application is based on and claims priority from Japanese Patent Application No. 2022-139198, filed on Sep. 1, 2022, with the Japan Patent Office, the disclosure of which is incorporated herein in its entirety by reference.

### TECHNICAL FIELD

The present disclosure relates to a plasma processing apparatus.

### BACKGROUND

Japanese Patent Laid-Open Publication No. 2020-043221 discloses a substrate processing apparatus, which includes a reaction tube that forms a processing chamber where a substrate is processed, an electrode fixing jig that is provided outside the reaction tube to fix electrodes for forming plasma in the processing chamber, and a heating device provided outside the electrode fixing jig to heat the reaction tube. The electrodes include an electrode to which an arbitrary potential is applied, and an electrode to which a reference potential is given. The surface area of the electrode, to which the arbitrary potential is applied, is twice or more the surface area of the electrode, to which the reference potential is given.

### SUMMARY

According to an aspect of the present disclosure, a plasma processing apparatus includes: a processing container; a substrate holding unit that disposes a plurality of substrates in multiple tiers and is inserted into the processing container; a rotary shaft that rotates the substrate holding unit; a gas supply unit that supplies a processing gas into the processing container; an exhaust unit that exhausts the inside of the processing container; a plurality of electrodes disposed on the outer side of the processing container and arranged in the circumferential direction of the processing container; and a radio-frequency power supply that applies a radio-frequency power to the plurality of electrodes, and generates capacitively coupled plasma in the processing container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an example of a configuration of a plasma processing apparatus.

FIG. 2 is a schematic view illustrating an example of the configuration of the plasma processing apparatus, which is taken by cutting a processing container horizontally.

FIG. 3 is a schematic view illustrating another example of the configuration of the plasma processing apparatus, which is taken by cutting the processing container horizontally.

FIG. 4 is a schematic view illustrating yet another example of the configuration of the plasma processing apparatus, which is taken by cutting the processing container horizontally.

FIG. 5 is an example of a graph illustrating an electric field intensity in a Y-axis direction.

FIG. 6 is an example of a graph illustrating an electric field intensity in an X-axis direction.

FIG. 7 is an example of a graph illustrating a radio-frequency power applied to each electrode.

FIG. 8 is an example of a graph illustrating an electric field intensity in a Y-axis direction.

FIG. 9 is an example of a graph illustrating an electric field intensity in a circumferential direction.

FIG. 10 is another example of the graph illustrating the radio-frequency power applied to each electrode.

FIG. 11 is yet another example of the graph illustrating the radio-frequency power applied to each electrode.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In the respective drawings, the same components may be denoted by the same reference numerals, and overlapping descriptions thereof may be omitted.

[Plasma Processing Apparatus]

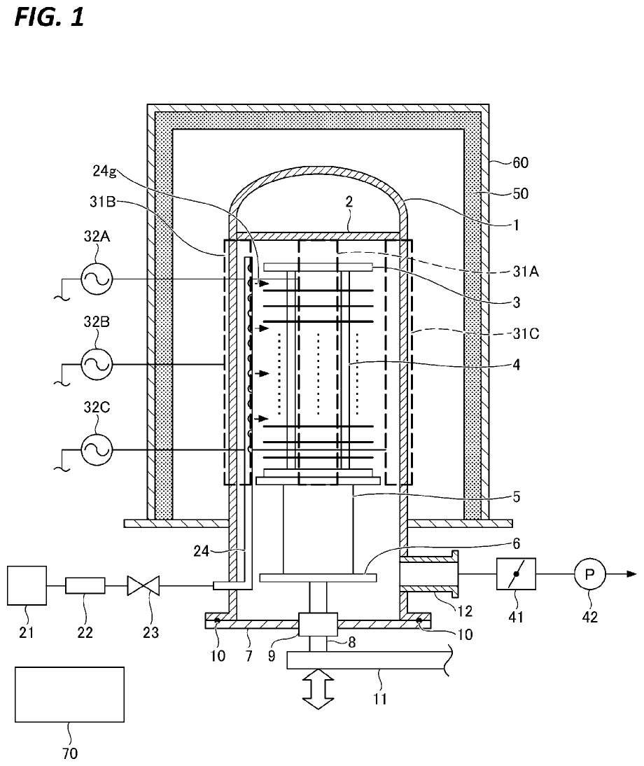

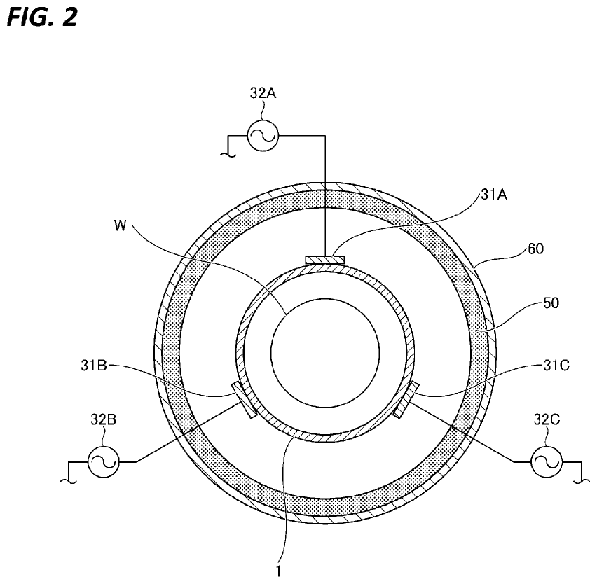

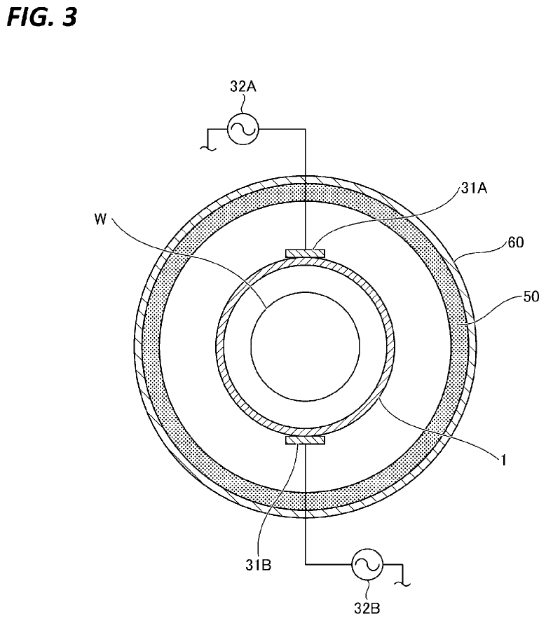

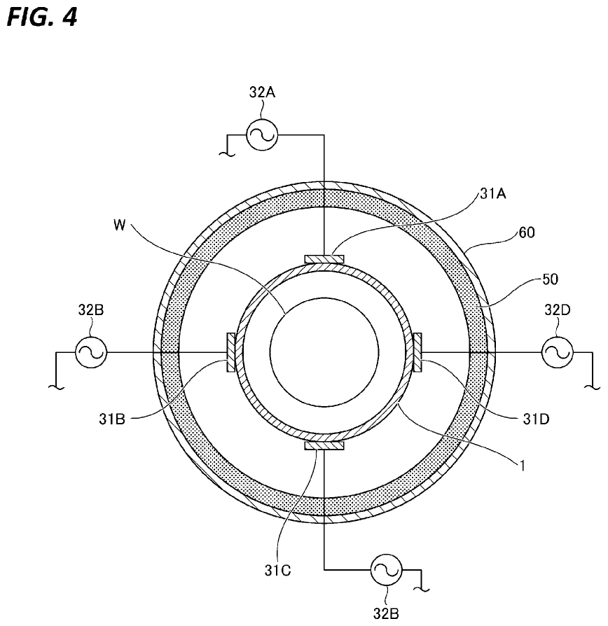

A plasma processing apparatus (substrate processing apparatus) according to an embodiment of the present disclosure will be described using FIGS. 1 and 2. FIG. 1 is a schematic view illustrating an example of a configuration of the plasma processing apparatus. FIG. 2 is a schematic view illustrating an example of the configuration of the plasma processing apparatus, which is taken by cutting a processing container 1 horizontally. FIG. 2 (and FIGS. 3 and 4 to be described later) omits the illustration of rods 4 and a gas supply pipe 24.

The plasma processing apparatus includes a processing container 1 having a shape of a ceilinged cylindrical body with an opening at the lower end thereof. The entire processing container 1 is formed of, for example, quartz. A ceiling plate 2 made of quartz is provided inside the processing container 1 near the upper end thereof, and the region below the ceiling plate 2 is sealed.

The lower portion of the processing container 1 is opened, and a wafer boat (substrate holding unit) 3, in which a plurality of (e.g., 25 to 150) semiconductor wafers (hereinafter, referred to as “substrates W”) are disposed in multiple tiers, is inserted into the processing container 1 from the lower portion of the processing container 1. In this way, the plurality of substrates W are accommodated substantially horizontally at intervals along the vertical direction inside the processing container 1. The wafer boat 3 is formed of, for example, quartz. The wafer boat 3 includes three rods 4 (of which two are illustrated in FIG. 1), and the plurality of substrates W are supported by grooves (not illustrated) formed in the rods 4.

The wafer boat 3 is disposed on a table 6 via a heat insulating cylinder 5 formed of quartz. The table 6 is supported on a rotary shaft 8 that penetrates a lid 7 capable of opening/closing the opening of the lower end of the processing container 1 and formed of a metal (stainless steel).

A magnetic fluid seal 9 is provided at the penetrating portion of the rotary shaft 8 to airtightly seal and rotatably support the rotary shaft 8. A seal member 10 is provided between the peripheral portion of the lid 7 and the lower end of the processing container 1, to maintain the airtightness inside the processing container 1.

The rotary shaft 8 is attached to the tip of an arm 11 supported by a lift mechanism (not illustrated) such as, for example, a boat elevator, and the wafer boat 3 moves up and down together with the lid 7 to be inserted and removed into/from the processing container 1. The table 6 may be provided to be fixed to the lid 7, such that the substrates W may be processed without rotating the wafer boat 3.

The plasma processing apparatus further includes a gas supply unit that supplies a predetermined gas such as a processing gas or a purge gas into the processing container 1.

The gas supply unit includes the gas supply pipe 24. The gas supply pipe 24 is formed of, for example, quartz, and penetrates the side wall of the processing container 1 inward to be bent upward and extend vertically. In the vertical portion of the gas supply pipe 24, a plurality of gas holes 24g is formed at predetermined intervals over the vertical length corresponding to the wafer supporting range of the wafer boat 3. Each gas hole 24g ejects a gas in the horizontal direction. A processing gas is supplied to the gas supply pipe 24 from a gas supply source 21 through a gas pipe. The gas pipe is provided with a flow rate controller 22 and an opening/closing valve 23. As a result, the processing gas from the gas supply source 21 is supplied into the processing container 1 through the gas pipe and the gas supply pipe 24. The flow rate controller 22 is configured to control the flow rate of the gas supplied from the gas supply pipe 24 into the processing container 1. The opening/closing valve 23 is configured to control the supply and the cut-off of the gas supplied from the gas supply pipe 24 into the processing container 1.

A plurality of electrodes 31 (31A to 31C) is provided on the outer side of the processing container 1. In the example illustrated in FIGS. 1 and 2, the three electrodes are provided including the electrode (first electrode) 31A, the electrode (second electrode) 31B, and the electrode (third electrode) 31C. The electrodes 31 (31A to 31C) are arranged at equal intervals (120° pitch) in the circumferential direction of the processing container 1. The electrodes 31 (31A to 31C) are formed of a good conductor such as metal. Radio-frequency power supplies 32 (32A to 32C) are connected to the electrodes 31 (31A to 31C), respectively, and are configured to vary the voltage and the phase of the radio-frequency power applied to each electrode 31 (31A to 31C). That is, the voltage and the phase of the radio-frequency power applied to each electrode 31 (31A to 31C) is variable.

The inside of the processing container 1 is exhausted by an exhaust device 42 to be described later, and thus, is decompressed (vacuum atmosphere). The processing gas from the gas supply pipe 24 is supplied into the processing container 1. Meanwhile, the outside of the processing container 1 is in the air atmosphere. The electrodes 31 (31A to 31C) are disposed in the space of the air atmosphere outside the processing container 1.

When the radio-frequency power from each radio-frequency power supply 32 (32A to 32C) is applied to each electrode 31 (31A to 31C), an electric field is formed in the processing container 1, so that capacitively coupled plasma (CCP) is formed in the processing container 1.

As illustrated in FIG. 1, the electrodes 31 (31A to 31C) are disposed in a wider range than a range in the height direction of the plurality of substrates W disposed in the wafer boat 3. That is, the electrodes 31 (31A to 31C) are formed up to a higher position than the uppermost substrate W disposed in the wafer boat 3, and are formed up to a lower position than the lowermost substrate W disposed in the wafer boat 3.

An exhaust port 12 is formed in the side wall of the processing container 1 to evacuate the inside of the processing container 1. The exhaust device (exhaust unit) 42 is connected to the exhaust port 12, and includes, for example, a pressure control valve 41 that controls the pressure in the processing container 1, and a vacuum pump. The inside of the processing container 1 is exhausted by the exhaust device 42 through an exhaust pipe.

A cylindrical heating mechanism 50 is provided around the processing container 1. The heating mechanism 50 is disposed to surround the processing container 1 and the plurality of electrodes 31 (31A to 31C). The space between the heating mechanism 50 and the processing container 1 is in the air atmosphere, and the plurality of electrodes 31 (31A to 31C) are disposed in the space. The heating mechanism 50 heats the processing container 1 and the substrates W inside the processing container 1. The heating mechanism 50 controls the temperature of the processing container 1 to reach a desired temperature (e.g., 600° C.). As a result, the substrates W inside the processing container 1 are heated by, for example, the radiant heat from the wall surface of the processing container 1.

A shield 60 is provided on the outer side of the heating mechanism 50. That is, the shield 60 is disposed to surround the processing container 1, the plurality of electrodes 31 (31A to 31C), and the heating mechanism 50. The shield 60 is formed of a good conductor such as metal, and is grounded.

The plasma processing apparatus 100 further includes a control unit 70. The control unit 70 controls, for example, the operation of each component of the plasma processing apparatus, such as the supply and the cut-off of each gas by the opening/closing of the opening/closing valve 23, the control of the gas flow rate by the flow rate controller 22, and the control of the exhaust by the exhaust device 42. Further, the control unit 70 controls, for example, the control of ON/OFF of the radio-frequency power by the radio-frequency power supplies 32 (32A to 32C) and the control of the temperatures of the processing container 1 and the substrates W therein by the heating mechanism 50.

The control unit 70 may be, for example, a computer. A storage medium stores a computer program for performing the operation of each component of the plasma processing apparatus. The storage medium may be, for example, a flexible disk, a compact disk, a hard disk, a flash memory, or a DVD.

With this configuration, the plasma processing apparatus may decompress the inside of the processing container 1 by the exhaust device 42, supply the processing gas into the processing container 1 from the gas supply pipe 24, and apply the radio-frequency power to the electrodes 31 (31A to 31C), thereby generating the capacitively coupled plasma (CCP) in the processing container 1, that a processing (e.g., etching or film formation) may be performed on the substrates W. Further, when performing the plasma processing on the substrates W, the wafer boat 3 may be rotated by the rotary shaft 8 so that the uniformity of the plasma processing in the circumferential direction of the substrates W may be improved.

In the example illustrated in FIGS. 1 and 2, the plasma processing apparatus includes the three electrodes 31 (31A to 31C) arranged on the outer side of the processing container 1, and the three radio-frequency power supplies 32 (32A to 32C) connected to the electrodes 31 (31A to 31C), respectively. However, the present disclosure is not limited to this configuration.

FIG. 3 is a schematic view illustrating another example of the configuration of the plasma processing apparatus, which is taken by cutting the processing container 1 horizontally. As illustrated in FIG. 3, the plasma processing apparatus may be configured to include two electrodes 31 (31A and 31B) arranged at equal intervals (180° pitch) on the outer side of the processing container 1, and two radio-frequency power supplies 32 (32A and 32B) connected to the electrodes 31 (31A and 31B), respectively.

FIG. 4 is a schematic view illustrating yet another example of the configuration of the plasma processing apparatus, which is taken by cutting the processing container 1 horizontally. As illustrated in FIG. 4, the plasma processing apparatus may be configured to include four electrodes 31 (31A to 31D) arranged at equal intervals (90° pitch) on the outer side of the processing container 1, and four radio-frequency power supplies 32 (32A to 32D) connected to the electrodes 31 (31A to 31D), respectively. Further, the plasma processing apparatus may be configured to include five or more electrodes 31 and five or more radio-frequency power supplies 32.

In FIGS. 2 to 4, the plurality of electrodes 31 are provided at equal intervals in the circumferential direction of the processing container 1. However, the present disclosure is not limited to this configuration. The plurality of electrodes 31 may not be arranged at equal intervals.

In the descriptions above, the number of electrodes 31 and the number of radio-frequency power supplies 32 are the same. However, without being limited thereto, the number of electrodes 31 and the number of radio-frequency power supplies 32 may be different. For example, two or more electrodes 31 may be connected to one radio-frequency power supply 32.

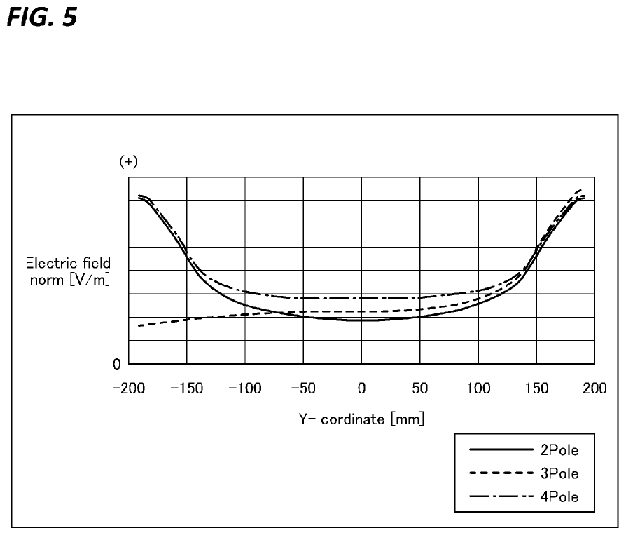

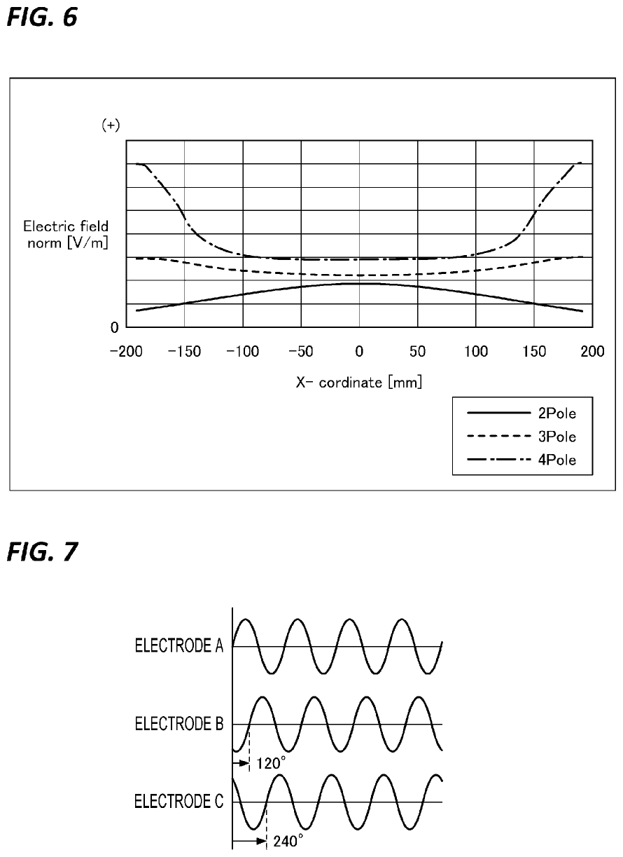

FIG. 5 is an example of a graph illustrating the electric field intensity in the Y-axis direction. FIG. 6 is an example of a graph illustrating the electric field intensity in the X-axis direction. Here, the axis connecting the electrode 31A and the center of the substrate W is referred to as the Y axis (the vertical direction of the paper in FIGS. 2 to 4), and the direction orthogonal to the Y axis is referred to as the X axis (the right-left direction of the paper in FIGS. 2 to 4). The horizontal axis of FIG. 5 represents the distance from the center of the substrate W, assuming that the center of the substrate W is 0 mm of the Y-axis direction, and the side of the electrode 31A is the plus side of the Y axis. The vertical axis of FIG. 5 represents the electric field intensity. The horizontal axis of FIG. 6 represents the distance from the center of the substrate W, assuming that the center of the substrate W is 0 mm of the X-axis direction. The vertical axis of FIG. 6 represents the electric field intensity.

The graph 2Pole illustrated by a solid line represents the electric field intensity in a case where radio-frequency powers of the same voltage are applied at phase differences of 0° and 180° to the two electrodes 31A and 31B illustrated in FIG. 3. The graph 3Pole illustrated by a dashed line represents the electric field intensity in a case where radio-frequency powers of the same voltage are applied at phase differences of 0°, 120°, and 240° to the three electrodes 31A to 31C illustrated in FIG. 2. The graph 4Pole illustrated by an alternate long and short dash line represents the electric field intensity in a case where radio-frequency powers of the same voltage are applied at phase differences of 0°, 90°, 180°, and 270° to the four electrodes 31A to 31D illustrated in FIG. 4.

As illustrated in FIGS. 5 and 6, by changing the number and the arrangement of the electrodes 31, the distribution of the electric field intensity in the plane of the substrate W may be adjusted. Accordingly, the in-plane uniformity of the plasma processing performed on the substrate W may be controlled.

For example, as represented in the graph 4Pole illustrated by the alternate long and short dash line, the electric field intensity may be flattened from the center of the substrate W toward the outside thereof in the radial direction. As a result, when performing the plasma processing on the substrate W, the wafer boat 3 is rotated by the rotary shaft 8 so that the uniformity of the plasma processing in the radial direction of the substrate W may be improved.

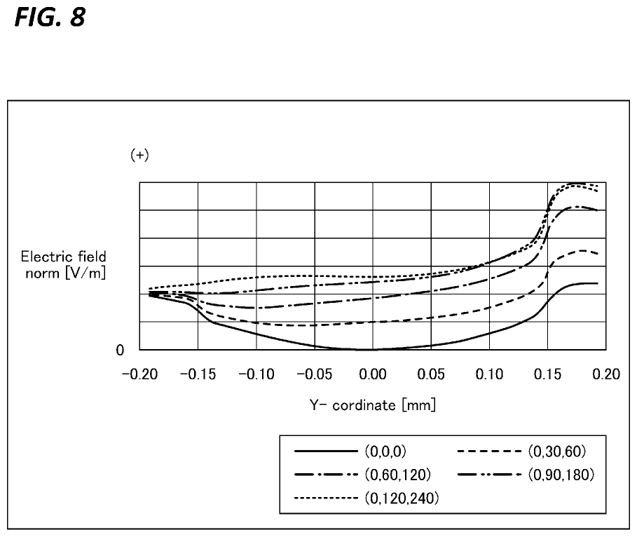

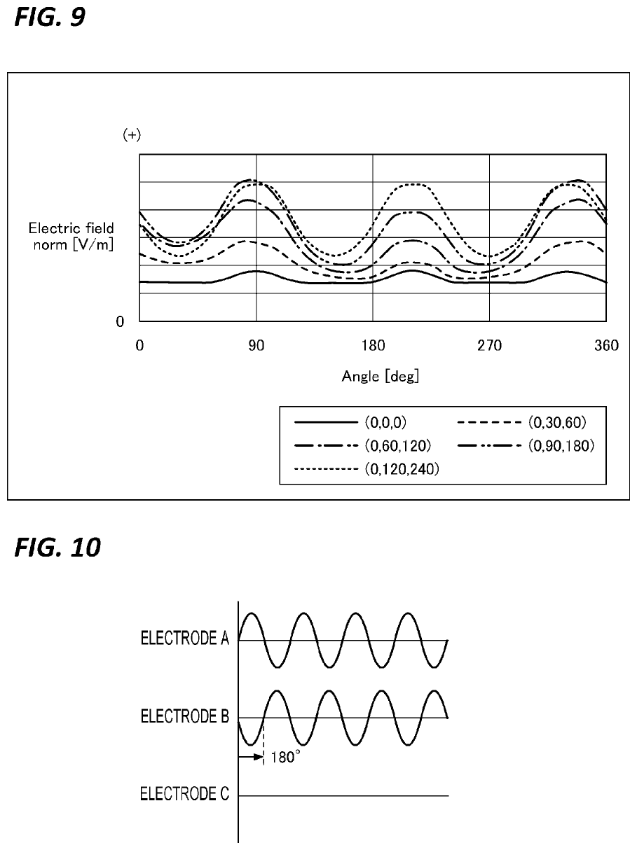

FIG. 7 is an example of a graph illustrating a radio-frequency power applied to each of the electrodes 31A to 31C. Here, the phase difference between the radio-frequency power applied to the electrode 31A and the radio-frequency power applied to the electrode 31B is equal to the phase difference between the radio-frequency power applied to the electrode 31B and the radio-frequency power applied to the electrode 31C. Specifically, FIG. 7 represents a case where radio-frequency powers of the same frequency are applied at phase differences of 0°, 120°, and 240° to the electrodes 31A to 31C. FIG. 8 is an example of a graph illustrating the electric field intensity in the Y-axis direction. FIG. 9 is an example of a graph illustrating the electric field intensity in the circumferential direction. The horizontal axis of FIG. 8 represents the distance from the center of the substrate W, assuming that the center of the substrate W is 0 mm of the Y-axis direction, and the side of the electrode 31A is the plus side of the Y axis. The vertical axis of FIG. 8 represents the electric field intensity. The horizontal axis of FIG. 9 represents the electric field intensity in the circumferential direction at a position 150 mm away from the center of the substrate W. The vertical axis of FIG. 9 represents the electric field intensity.

The graph (0, 0, 0) illustrated by a solid line represents the electric field intensity in a case where radio-frequency powers of the same voltage are applied at phase differences of 0°, 0°, and 0° to the three electrodes 31A to 31C illustrated in FIG. 2. The graph (0, 30, 60) illustrated by a dashed line represents the electric field intensity in a case where radio-frequency powers of the same voltage are applied at phase differences of 0°, 30°, and 60° to the three electrodes 31A to 31C illustrated in FIG. 3. The graph (0, 30, 60) illustrated by an alternate long and short dash line represents the electric field intensity in a case where radio-frequency powers of the same voltage are applied at phase differences of 0°, 60°, and 120° to the three electrodes 31A to 31C illustrated in FIG. 3. The graph (0, 90, 180) illustrated by an alternate one long and two short dash line represents the electric field intensity in a case where radio-frequency powers of the same voltage are applied at phase differences of 0°, 90°, and 180° to the three electrodes 31A to 31C illustrated in FIG. 3. The graph (0, 120, 240) illustrated by a dotted line represents the electric field intensity in a case where radio-frequency powers of the same voltage are applied at phase differences of 0°, 120°, and 240° to the three electrodes 31A to 31C illustrated in FIG. 3. FIG. 7 corresponds to the graph (0, 120, 240) illustrated by the dotted line.

As illustrated in FIGS. 8 and 9, by changing the phase of the radio-frequency power applied to each electrode 31, the distribution of the electric field intensity in the plane of the substrate W may be adjusted. Accordingly, the in-plane uniformity of the plasma processing performed on the substrate W may be controlled.

FIG. 10 is another example of the graph illustrating the radio-frequency power applied to each of the electrodes 31A to 3C. Without being applied to one of the plurality of electrodes 31, the radio-frequency power may be applied to the other electrodes. For example, in the example illustrated in FIG. 10, the radio-frequency power supply 32 may control the radio-frequency power to be applied to the electrodes 31A and 31B without being applied to the electrode 31C. Further, the phase difference between the radio-frequency power applied to the electrode 31A and the radio-frequency power applied to the electrode 31B may be controlled to be 180°.

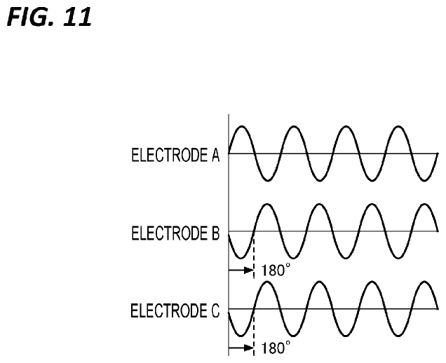

FIG. 11 is yet another example of the graph illustrating the radio-frequency power applied to each of the electrodes 31A to 31C. The phase of the radio-frequency power applied to any one of the plurality of electrodes 31 may be equal to another of the plurality of electrodes 31. As a result, the distribution of the electric field intensity in the plane of the substrate W may be varied. For example, in the example illustrated in FIG. 11, the radio-frequency power applied to the electrode 31B and the radio-frequency power applied to the electrode 31C may be controlled to have the same phase. Further, the phase difference between the radio-frequency power applied to the electrode 31A and the radio-frequency power applied to the electrode 31B may be controlled to be 180°.

As described above, the voltage and the phase of the radio-frequency power applied to each of the electrodes 31A to 31C may be varied. Thus, the electric field intensity in the radial direction of the substrate W may be adjusted. As a result, for example, the average value of the electric field intensity at the center and the outer periphery of the substrate W may be made constant. As a result, the in-plane uniformity of the substrate processing may be improved.

According to an aspect, it is possible to provide a plasma processing apparatus capable of adjusting the electromagnetic field intensity distribution in the plane of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container;
a substrate holder configured to dispose a plurality of substrates in multiple tiers and be inserted into the processing container;
a rotary shaft configured to rotate the substrate holder;
a gas supply configured to supply a processing gas into the processing container;
an exhaust configured to exhaust an inside of the processing container;
a plurality of electrodes disposed on an outer side of the processing container and arranged in a circumferential direction of the processing container; and
a radio-frequency power supply configured to apply a radio-frequency power to the plurality of electrodes and generate capacitively coupled plasma in the processing container.

2. The plasma processing apparatus according to claim 1, wherein the radio-frequency power supply is configured to vary a voltage and a phase of the radio-frequency power applied to each of the plurality of electrodes.

3. The plasma processing apparatus according to claim 1, wherein the plurality of electrodes are disposed in a wider range than a range in a height direction of the plurality of substrates disposed in the substrate holder.

4. The plasma processing apparatus according to claim 1, wherein the plurality of electrodes are arranged at equal intervals in the circumferential direction of the processing container.

5. The plasma processing apparatus according to claim 1, further comprising:
a heater configured to surround the processing container and the plurality of electrodes.

6. The plasma processing apparatus according to claim 5, further comprising:
a shield configured to surround the processing container, the plurality of electrodes, and the heater.

7. The plasma processing apparatus according to claim 6, wherein the shield is grounded.

8. The plasma processing apparatus according to claim 1, wherein the plurality of electrodes include a first electrode, a second electrode, and a third electrode.

9. The plasma processing apparatus according to claim 8, wherein a phase difference between the radio-frequency power applied to the first electrode and the radio-frequency power applied to the second electrode is equal to a phase difference between the radio-frequency power applied to the second electrode and the radio-frequency power applied to the third electrode.

10. The plasma processing apparatus according to claim 8, wherein the radio-frequency power supply is configured such that the radio-frequency power is applied to the first and second electrodes, but is not applied to the third electrode.

11. The plasma processing apparatus according to claim 8, wherein a phase difference between the radio-frequency power applied to the first electrode and the radio-frequency power applied to the second electrode is 180°.

12. The plasma processing apparatus according to claim 8, wherein a phase of the radio-frequency power applied to the second electrode and a phase of the radio-frequency power applied to the third electrode are substantially equal.

13. The plasma processing apparatus according to claim 12, wherein a phase difference between the radio-frequency power applied to the first electrode and the radio-frequency power applied to the second electrode is 180°.
